(19) United States
(12) Patent Application Publication
(10) Pub. No.: US 2004/0259345 A1
(43) Pub. Date: Dec. 23, 2004

(54) Formation method of conductive bump

(76) Inventors: Jui-I Yu, Kaohsiung City (TW); Feng-Cheng Tai, Kaohsiung (TW)

Correspondence Address: BIRCH STEWART KOLASCH & BIRCH, PO BOX 747, FALLS CHURCH, VA, 22040-0747, US

(21) Appl. No.: 10/864,338

(22) Filed: Jun. 10, 2004

(30) Foreign Application Priority Data
Jun. 19, 2003 (TW) 092116683

(51) Int. Cl. H01L 21/44

(52) U.S. Cl. 438/613

(57) ABSTRACT

A formation method for a conductive bump is provided. A semiconductor structure has a conductive surface thereon. A photo resist layer is formed first and then removed in part to have an under-cut opening exposing the conductive surface. An under-bump-metallurgy layer is formed on the exposed conductive surface and the photo resist layer exclusive of the sidewall of the under-cut opening, and then a conductive material is subsequently formed on the under-bump-metallurgy layer and is then reflowed to form a conductive bump. Finally, the photo resist layer and the under-bump-metallurgy layer thereon are removed. The configuration feature of under-cut photo resist layer provides the disconnected formation of the under bump metallurgy structure, thus the whole manufacture process is simplified and the manufacture cost reduces.

### BACKGROUND OF THE INVENTION

1. Field of the Invention

The present invention generally relates to a formation method of a conductive bump and more particularly to a formation method of solder bump or gold stud.

2. Description of the Prior Art

Following the development of integrated circuit technology, the packing requirement is more and more strict for the IC (integrated circuit), because the packaging technology is directly related to the function of the electronic products. The conventional packaging methods include DIP (Dual In-line Package), QFP (Quad Flat Package), and PFP (Plastic Flat Package). When the frequency of IC exceeds 100 MHz, the conventional packaging method generates a phenomenon called “Cross-Talk”. Furthermore, when the number of pins is larger than 208, the packaging becomes more difficult in the conventional packaging technology. In addition to the QFP technology, the BGA (ball grid array package) technology is the most popular packaging technology if the chip has many pins, such as graphic chips and chip module. Thus, in the present, the BGA technology is the best choice for the chip with a high density, and high performance, and multitudes of pins such as CPU (central processing unit) and south/north bridges chip on/in the motherboard.

On the other hand, the BGA packaging technology can be classified into five types: PBGA (Plastic BGA) substrate, CBGA (Ceramic BGA) substrate, FCBGA (Flip chip BGA) substrate, TBGA (Tape BGA) substrate, and CDPBGA (Cavity Down PBGA) substrate. In the conventional, the IC packaging process which is packaged from a single IC, which needs a leadframe or substrate, and also include some processes such as the die attach, bonding, molding, or trim and form processes, such that the chip size of the packaged IC is greater than the chip after the IC is packaged. FCBGA is a type that use gold or solder bumps on an IC chip for soldering PCB. In the assembly of a flip chip on a PCB, the active side of the chip is faced downward and interface material is added between the chip and the solder bumps. Nowadays, a chip scale package (CSP) is a development to have the size of a chip package identical to the size of the chip. Moreover, a enhanced ball grid array package solves the problems of electrical interference and heat dissipation resulting from the size shrinking of IC.

For example, shown in FIGS. 1A to 1G are schematic cross-sectional diagrams illustrating conventional fabrication of solder bump by thin film deposition. Depicted in FIG. 1A are a bonding pad 114, a passivation layer 120 and a conductive layer 122 on a silicon wafer 112. The bonding pad 114, such as alumnus or copper pad, is configured to electrically connect an exterior circuit. The passivation layer 120, which exposes the partial surface 118 of the bonding pad 114, is configured to provide the wafer 112 with protection and planarization. The conductive layer 122, such as an under bump metallurgy layer (UBM layer) formed by sputtering, covers the passivation layer 120 and the surface 118. It is noted that the under bump metallurgy layer consisting of an adhesive/diffusion barrier and a wetting layers can improve the adhesion between a solder ball and the surface 118.

Next, a photo-resist film, such as a dry film or liquid photo-resist, covers the conductive layer 122. Shown in FIG. 1B, a patterned photo-resist layer 128 is transferred onto the bonding pad 114 by photolithography and a partial removal of the photo-resist layer. Next, with the patterned photo-resist layer 128 as a mask, the conductive layer 122 is implemented by photolithography for pattern transferring and removing a portion by a wet etching method to keep the portion of the conductive layer 122 on the bonding pad 114. Then the patterned photo-resist layer 128 is stripped, shown in FIG. 1C.

Another photo-resist layer 134 covers the whole surface first and is then pattern-transferred to form an opening 138 for the position of the solder ball, as depicted in FIG. 1D. Shown in FIG. 1E, solder bump 140 is printed into the opening 138. The solder bump 140 is thus accomplished through a reflow process for the formation of solder ball, as shown in FIG. 1F. The photo-resist layer 134 is removed shown in FIG. 1G.

Accordingly, it is necessary for such a conventional process to form photo-resist layers many times. Furthermore, the costs are higher and a longer time is spent to execute the removal of unwanted conductive material by wet etching in the conventional process.

### SUMMARY OF THE INVENTION

Accordingly, a formation method of conductive bumps is provided with simplified steps without photolithography many times.

For cost reduction of manufacturing conductive bumps, a formation method of bump electrode provided with the formation of dry film in under cut shape fits the printing of conductive bumps.

A formation method for a conductive bump is provided. A semiconductor structure has a conductive surface thereon. A photo resist layer is formed first and then removed in part to have an under-cut opening exposing the conductive surface. An under-bump-metallurgy layer is formed on the exposed conductive surface and the photo resist layer exclusive of the sidewall of the under-cut opening, and then a conductive material is subsequently formed on the under-bump-metallurgy layer and is then reflowed to form a conductive bump. Finally, the photo resist layer and the under-bump-metallurgy layer thereon are removed. The configuration feature of under-cut photo resist layer provides the disconnected formation of the under bump metallurgy structure, thus the whole manufacture process is simplified and the manufacture cost reduces.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1G are schematic cross-sectional diagrams illustrating conventional fabrication of solder bump by thin film deposition;

FIGS. 2A to 2E are the schematic cross-sectional diagrams illustrating the manufacture of conductive bumps in accordance with one embodiment of the present invention.

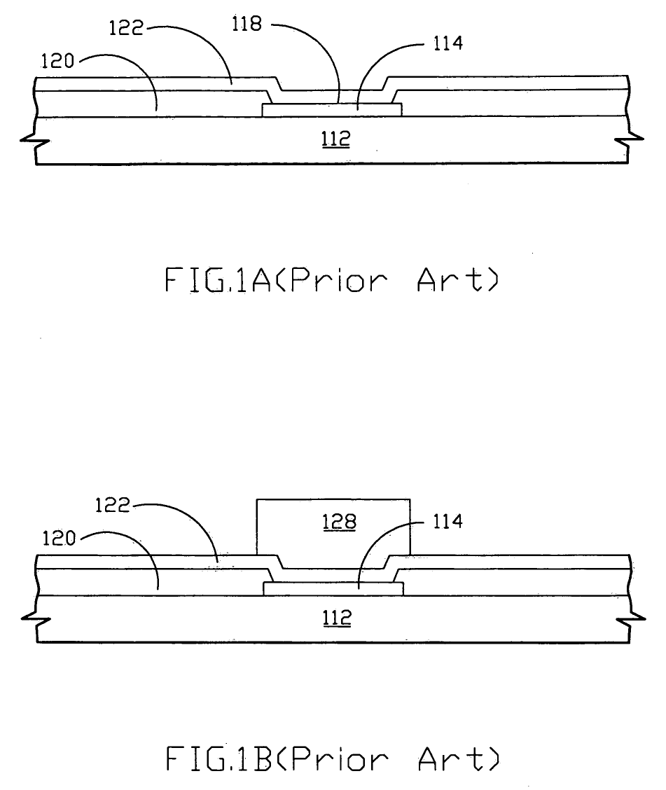

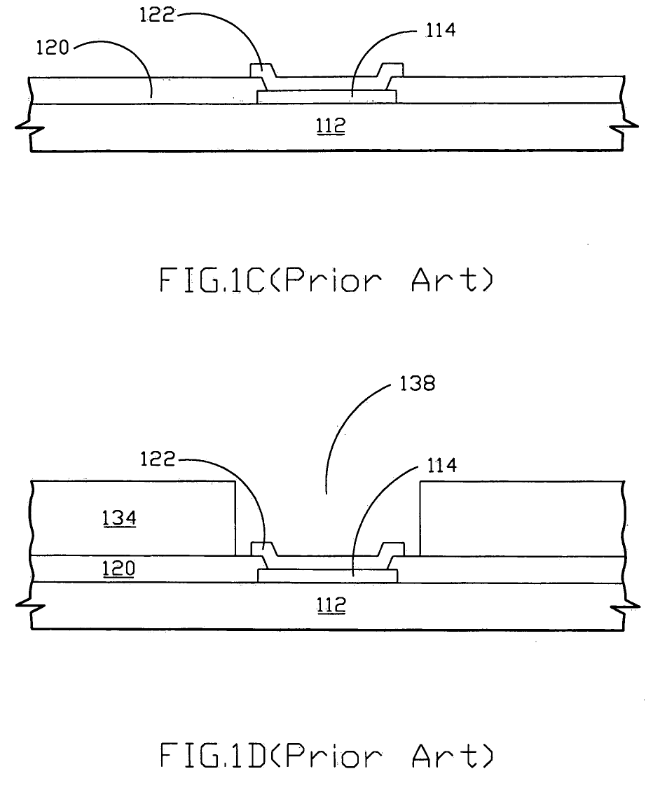

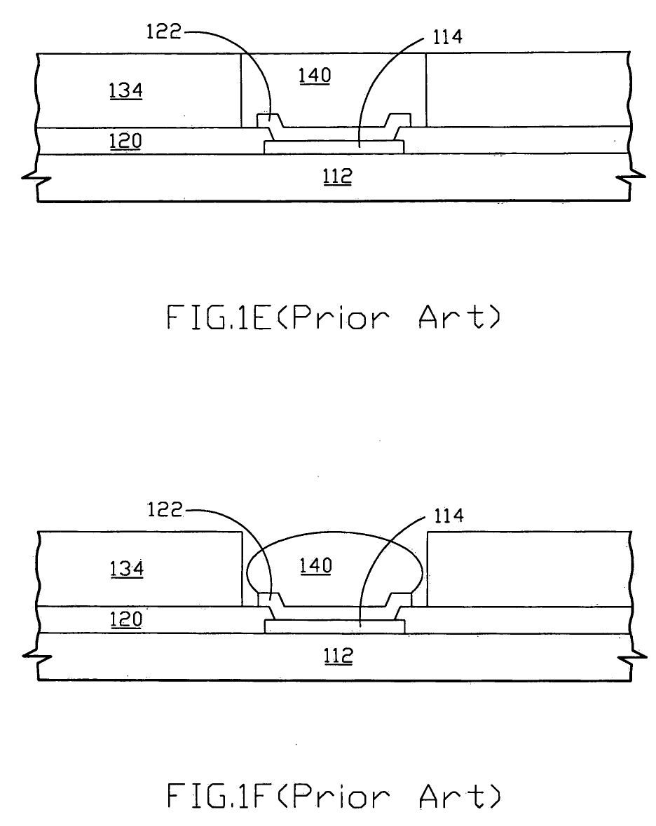

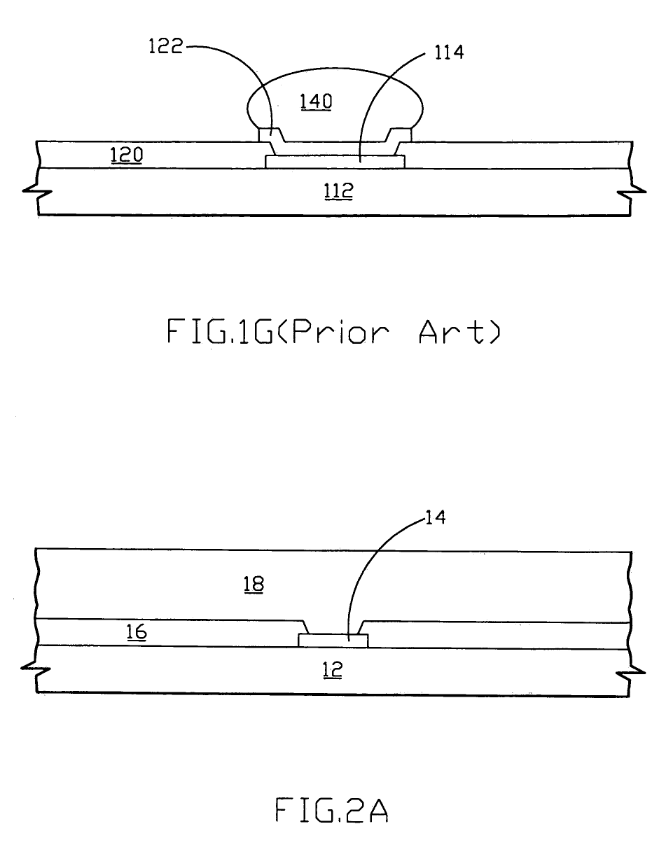

### DESCRIPTION OF THE PREFERRED EMBODIMENTS

Before describing the invention in detail, a brief discussion of some underlying concepts will first be provided to facilitate a complete understanding of the invention.

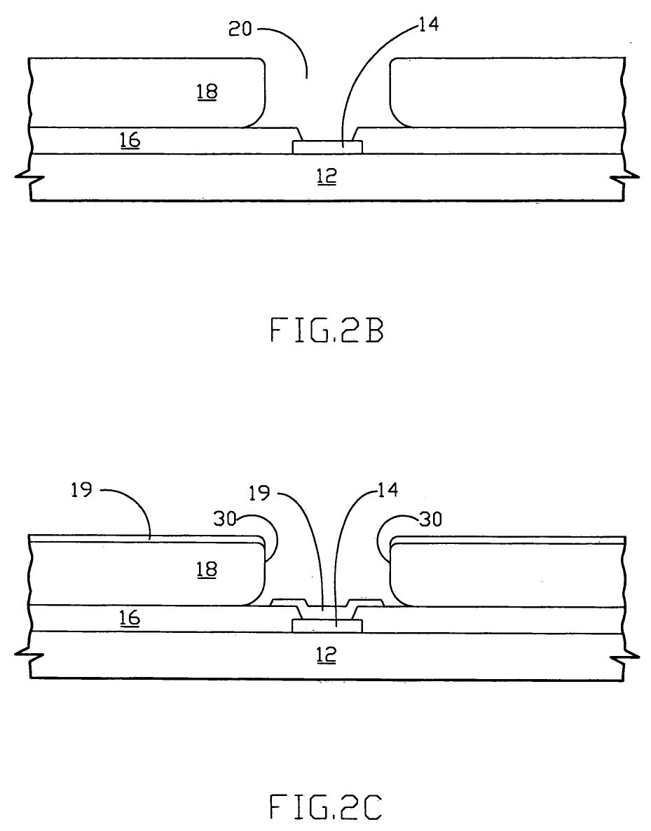

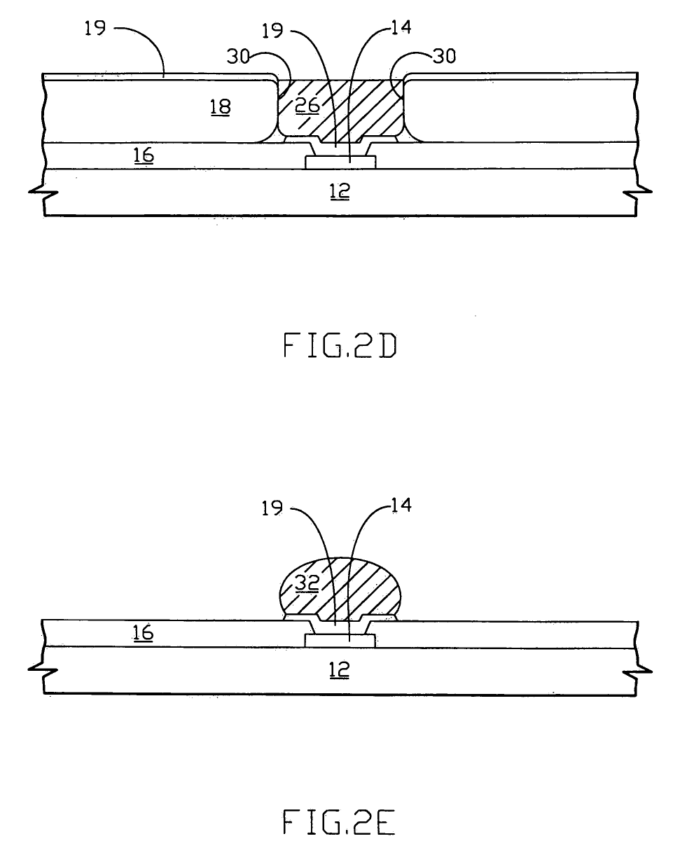

FIGS. 2A to 2E are the schematic cross-sectional diagrams illustrating the manufacture of conductive bumps in accordance with one embodiment of the present invention. Depicted in FIG. 2A, a semiconductor structure includes a wafer 12, a conductive structure 14, a dielectric layer 16 and a photo-resist layer 18. The wafer 12 is a silicon wafer and may have other semiconductor devices thereon. The conductive structure 14, such as an aluminum or copper bonding pad, is formed by any suitable methods and configured for the electric connection with an exterior circuit. The dielectric layer 16, such as oxide, nitride, or other organic material as a passivation layer, provides the semiconductor structure with protection and planarization. Furthermore, it is noted that the dielectric layer 16 exposes the partial surface, i.e. conductive surface of the conductive structure 14. The photo-resist layer 18 is either a negative photo-resist layer formed by a coating or a dry film, which covers over the dielectric layer 16 or the exposed surface of conductive structure 14.

Depicted in FIG. 2B, a pattern is transferred through photolithography to form an opening 20 in the photo-resist layer 18. In an embodiment, the photo-resist layer 18 having the opening 20 is of an under cut configuration implemented by prolongation of exposure, over development or distance adjustment between a mask and the photo-resist layer 18. In the embodiment of the present invention, with use of the opening 20 of under cut configuration, an under bump metallurgy layer can be formed subsequent to the formation of the opening 20, thus only one photo-resist layer is necessary, instead of two layers in a conventional process.

Furthermore, depicted in FIG. 2C, a under bump metallurgy structure 19 is formed on the exposed conductive surface of the conductive structure 14 and in the opening 20. In the embodiment, the under bump metallurgy structure 19 includes an aluminum layer, a nickel-vanadium layer and a copper layer sequentially formed on the exposed conductive surface of the conductive structure 14. In the embodiment, the aluminum layer, the nickel-vanadium layer and the copper layer are formed by sputtering metal and constitute the under bump metallurgy structure 19. It is noted that the photo-resist layer 18 with the opening 20 of an under cut configuration is used as a mask to prevent the under bump metallurgy structure 19 from a consecutive formation. That is, the aluminum layer, the nickel-vanadium layer and the copper layer are formed on the exposed conductive surface rather than the sidewall 30 of the opening 20. By utilizing the photo-resist layer 18 with the opening of under cut configuration, an under bump metallurgy structure is formed of a suitable size instead of an adjustment through an etching process. Thus, the embodiment provides a simplified process for formation of the under bump metallurgy structure.

Next, shown in FIG. 2D, conductive material 26 is filled into the opening 20 and on the under bump metallurgy structure 19. In the embodiment, the conductive material 26, such as solder paste, can be filled into the opening 20 by printing. Alternatively, the conductive material 26, such as solder, can be filled into the opening 20 by electrode position to form a solder bump. It is understandable that the conductive material 26 can be gold to form gold stud in the opening 20. The embodiment applies on the manufacture of solder bump of 150 mm, 200 mm or 300 mm size. Next, shown in FIG. 2E, the photo-resist layer 18 is removed by stripping. Furthermore, the conductive material 26 is through reflowing for formation of the solder ball 32 or gold stud for the use of a bump electrode.

A formation method of conductive bump is provided aforementioned. A wafer has a bonding pad and a passivation layer is formed over the wafer but exposes a conductive surface of the bonding pad. A photo-resist layer is formed on the passivation layer and the conductive surface. A portion of the photo-resist layer is removed to provide an opening exposing the conductive surface. The opening is with a sidewall of under cut configuration. Then an aluminum layer, nickel-vanadium layer and copper layer are sequentially sputtered on the conductive surface and the photo-resist layer but not on the sidewall of under cut configuration. A conductive material is then filled on the copper layer in the opening and next reflowed to form a conductive bump.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A formation method of conductive bump, comprising:
providing a semiconductor structure including a conductive surface exposed thereon;
forming a photo-resist layer on said semiconductor structure;
removing a portion of said photo-resist layer to provide an opening exposing said conductive surface, wherein said opening is with a sidewall of under cut configuration;
forming a under bump metallurgy structure on said conductive surface and said photo-resist layer, wherein said under bump metallurgy structure is not formed on said sidewall of under cut configuration;
forming a conductive material on said under bump metallurgy structure in said opening;
reflowing said conductive material to form a conductive bump; and
removing said photo-resist layer and said under bump metallurgy structure on said photor-resist layer.

2. The formation method of conductive bump according to claim 1, wherein the providing step comprises:
providing a silicon wafer;
foming a conductive structure on said silicon wafer; and
forming a passivation layer over said silicon wafer and a portion of said conductive structure to expose a portion of said conductive surface.

3. The formation method of conductive bump according to claim 2, wherein the step of forming said conductive structure comprises forming an aluminum bonding pad by sputtering.

4. The formation method of conductive bump according to claim 1, wherein the step of forming said photo-resist layer comprises:
coating said photo-resist layer over said semiconductor structure and said conductive surface; and
pattern-transferring said photo-resist layer.

5. The formation method of conductive bump according to claim 1, wherein the step of forming said under bump metallurgy structure comprises:
sputtering an aluminum layer on said conductive surface;
sputtering a nickel-vanadium layer on said aluminum layer; and
sputtering a copper layer on said nickel-vanadium layer.

6. The formation method of conductive bump according to claim 1, wherein the step of forming said conductive material comprises printing a solder paste on said under bump metallurgy structure.

7. The formation method of conductive bump according to claim 1, wherein the step of forming said conductive material comprises electrodepositing a solder on said under bump metallurgy structure.

8. The formation method of conductive bump according to claim 1, wherein the step of forming said conductive bump comprises forming a gold stud on said under bump metallurgy structure.

9. A formation method of conductive bump, comprising:
providing a wafer having a bonding pad thereon;
forming a passivation layer over said wafer to expose a conductive surface of said bonding pad;
forming a photo-resist layer on said passivation layer and said conductive surface;
removing a portion of said photo-resist layer to provide an opening exposing said conductive surface, wherein said opening is with a sidewall of under cut configuration;
sputtering an aluminum layer on said conductive surface and said photo-resist layer, wherein said aluminum layer is not formed on said sidewall of under cut configuration;
sputtering a nickel-vanadium layer on said aluminum layer;
sputtering a copper layer on said nickel-vanadium layer;
filling a conductive material on said copper layer in said opening; and
reflowing said conductive material to form a conductive bump.

10. The formation method of conductive bump according to claim 9, wherein said bonding pad is an aluminum pad.

11. The formation method of conductive bump according to claim 9, wherein said bonding pad is a copper pad.

12. The formation method of conductive bump according to claim 9, wherein the step of forming said photo-resist layer comprises coating a negative photo-resist layer.

13. The formation method of conductive bump according to claim 9, wherein the step of forming said photo-resist layer comprises forming a dry film.

14. The formation method of conductive bump according to claim 9, wherein the step of filling said conductive material comprises printing a solder paste into said opening.

15. The formation method of conductive bump according to claim 9, wherein the step of filling said conductive material comprises electrodepositing a solder into said opening.

16. The formation method of conductive bump according to claim 9, wherein the step of filling said conductive material comprises forming a gold stud into said opening.

17. The formation method of conductive bump according to claim 9, further comprising stripping said photo-resist layer after the filling step.
